(19) United States
(12) Patent Application Publication
(10) Pub. No.: US 2004/0182542 A1
(43) Pub. Date: Sep. 23, 2004

(54) Heat sink

(76) Inventors: Koichiro Take, Oyama-shi (JP); Ichiro Iwai, Oyama-shi (JP); Yoshihiro Hayashida, Oyama-shi (JP); Makoto Fujioka, Oyama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/475,321

(22) PCT Filed: Apr. 23, 2002
(86) PCT No.: PCT/JP02/04010

Related U.S. Application Data
(60) Provisional application No. 60/356,122, filed on Feb. 14, 2002.

(30) Foreign Application Priority Data
Apr. 23, 2001 (JP) 2001-124815
Dec. 7, 2001 (JP) 2001-374689

(51) Int. Cl. H05K 7/20

(52) U.S. Cl. 165/80.3; 165/185

(57) ABSTRACT

The invention relates to heat sinks made of finned aluminum extrudates and useful for electronic devices and information devices having an electronic device incorporated therein. The heat sink of the invention made of a finned aluminum extrudate comprises a base plate, and fins arranged in parallel and provided on one surface thereof. The base plate is 25 to 400 mm in width, 25 to 400 mm in length and 2 to 5 mm in thickness, and the fins are 1 to 30 mm in height, 1 to 1.9 mm in interval and 0.1 to 0.8 mm in thickness. The thickness of the fins is reduced within a predetermined range according to the invention to thereby ensure diminished resistance to the flow of air and improved radiation performance. This also renders the heat sink lightweight, serving to reduce the size and weight of electronic devices and information devices.

### CROSS REFERENCE TO RELATED APPLICATIONS

This application is an application filed under 35 U.S.C. §111(a) claiming the benefit pursuant to 35 U.S.C. §119(e)(1) of the filing data of Provisional Application No. 60/356,122 filed Feb. 14, 2002 pursuant to 35 U.S.C. §111(b).

### TECHNICAL FIELD

The present invention relates to heat sinks made of finned aluminum extrudates and adapted, for example, for use in electronic devices and information devices having an electronic device incorporated therein.

The term “aluminum” as used herein includes aluminum alloys in addition to pure aluminum.

### BACKGROUND OF THE INVENTION

Heat sinks made of aluminum extrudates are generally in use for electronic devices and information devices having an electronic device incorporated therein for cooling heat generating elements such as thyristors, transistors, etc. However, with a marked increase in the quantity of heat generated by the components within the cases of electronic devices or information devices, there is a tendency for the heat generating density of heat generating elements to increase. Higher radiation performance is therefore required of heat sinks. The overall heat generating density of the interior of such cases also increases owing to a reduction in the size of cases. This results in a higher internal temperature of cases, and a further improved radiation efficiency is required of the heat sinks inside the cases. Further to diminish the noise of fans, it is desired to provide heat sinks which are reduced in the resistance to the flow of air. While decreases in the overall weight of electronic devices or information devices are also required, it is also desired that heat sinks be reduced in weight. Further the reduced sizes of cases impose limitations on the external dimensions of heat sinks. Thus, it is desired to provide compacted heat sinks of higher performance.

To enable heat sinks which are made of finned aluminum extrudates to exhibit higher radiation performance, it is effective to give an increased tongue ratio (ratio of the height of fins/the interval between fins). However, the increase in the tongue ratio is limited, for example, in view of the strength of the die used for producing finned aluminum extrudates.

An object of the present invention is to fulfill the foregoing requirements or request and to provide a highly efficient heat sink having fins which are reduced in thickness within a predetermined range to thereby ensure diminished resistance to the flow of air, improved radiation performance and a reduced weight, the heat sink consequently serving to reduce the size and weight of electronic devices and information devices incorporating an electronic device.

### DISCLOSURE OF THE INVENTION

The present invention provides a heat sink comprising a base plate, and fins arranged in parallel and provided on one surface thereof. The heat sink is characterized in that the base plate is 25 to 400 mm in width, 25 to 400 mm in length and 2 to 5 mm in thickness, the fins being 1 to 30 mm in height, 1 to 1.9 mm in interval, i.e., interval between the fins, and 0.1 to 0.8 mm in thickness.

With the heat sink of the present invention, the thickness of the fins is reduced within a predetermined range to thereby diminish the resistance to the flow of air and increase the number of fins per unit area of finned surface of the base plate. This renders the fins more efficient to enable the heat sink to exhibit improved radiation performance, further making the sink lightweight. When used, for example, in electronic devices and information devices incorporating an electronic device, the heat sink exhibits the advantages of ensuring very high radiation performance and a high efficiency, rendering the cases of the electronic devices and information devices small-sized and reducing the overall weight of these devices.

With the heat sink of the present invention, the base plate has a width of 25 to 400 mm, preferably 50 to 200 mm, at the front side thereof for introducing an air flow into the spaces between the fins. The base plate is limited to 25 to 400 mm in width because if the width is less than 25 mm, the heat sink consequently has a diminished front area to make the fin interval too small to result in increased resistance to the flow of air and impaired radiation efficiency. If the width is in excess of 400 mm, the heat sink fails to fit into the cases of electronic devices and information devices incorporating an electronic device which tend to become smaller in size, while the base plate becomes greater in diffusion heat resistance to entail impaired radiation performance. The heat sink then has an increased weight. The base plate is 25 to 400 mm, preferably 25 to 200 mm, in length along the lengthwise direction of the heat sink. The base plate is limited to 25 to 400 mm in length because if the length is less than 25 mm, the fins will have a diminished heat transfer area to result in lower radiation efficiency. If the length is in excess of 400 mm, the heat sink will have increased resistance to the flow of air, exhibit impaired radiation performance and become heavier, further failing to fit into the cases of electronic devices and information devices incorporating an electronic device which tend to become smaller in size.

The base plate is 2 to 5 mm, preferably 2 to 3 mm, in thickness. The thickness of the base plate is limited to 2 to 5 mm because if the thickness is less than 2 mm, the base plate becomes increased in diffusion heat resistance, and further because if the thickness is in excess of 5 mm, the heat sink becomes excessive in weight.

The fins are 1 to 30 mm, preferably 5 to 30 mm, more preferably 5 to 25 mm, in height. The height of the fins is limited to 1 to 30 mm because if the height is less than 1 mm, the fins have a diminished area to exhibit seriously impaired radiation performance. When the height is over 30 mm, an exceedingly great temperature drop occurs in the direction of height of the fins, leading to lower radiation performance.

The fins are 1 to 1.9 mm, preferably 1.5 to 1.9 mm, more preferably 1.6 to 1.8 mm in interval. The fin interval is limited to 1 to 1.9 mm because if the interval is less than 1 mm, the spaces between the fins offer greatly increased resistance to the flow of air to entail impaired radiation performance, whereas if the interval is in excess of 1.9 mm, the heat sink will have a diminished number of fins and a reduced heat dissipation area to exhibit lower radiation performance.

The fins are 0.1 to 0.8 mm, preferably 0.2 to 0.49 mm, in thickness. The fins are limited to 0.1 to 0.8 mm in thickness because if the thickness is less than 0.1 mm, the fins are difficult to extrude and have impaired strength, and further because thicknesses in excess of 0.8 mm reduce the fin interval to result in increased resistance to the flow of air and lower radiation performance, also giving an increased weight to the heat sink.

The heat sink is 0.53 to 30, preferably 2.7 to 24, in tongue ratio (H/L=the ratio of the height of the fins/the interval between the fins). If the tongue ratio is less than 0.53, the fin height is smaller relative to the fin interval to result in unsatisfactory radiation performance, whereas if the tongue ratio is over 30, the extrusion operation involves an impaired flow of the material within the die to produce void portions. In other words, the material then fails to fill up the space within the die and to afford fins with a predetermined height designed, forming undulating fins upon extrusion and permitting an uneven pressure to be applied for extrusion to possibly break the die, especially the fin forming portion thereof.

The performance of the heat sink with which the thickness of fins has relationship involves, for example, a reduction in the weight of the heat sink, reduction in the resistance to the flow of air and fin efficiency. The reduction of weight of the heat sink leads to an advantage, for example, of portable devices, directly resulting in a reduction of material cost. In this respect, the thinner the fins, the better. As to the resistance of the heat sink to the air flow, this resistance at the front side of the heat sink into which air streams are introduced decreases with a reduction in the thickness of the fins, consequently increasing the rate of flow of air available to improve the radiation performance. In this respect, the fins are preferably thinner. On the other hand, the reduction in the thickness of the fins gives rise to a temperature drop in the direction of height of the fins, i.e., a reduction in so-called fin efficiency, to entail impaired radiation performance. Accordingly, the radiation performance of the heat sink is determined, giving consideration to a balance between the decrease of air flow resistance due to the reduction of fin thickness and the reduction in fin efficiency.

### BRIEF DESCRIPTION OF THE DRAWINGS

FIG. 1 is a fragmentary perspective view of a heat sink made of a finned aluminum extrudate and according to the invention.

FIG. 2 is a graph showing the relationship between the fin interval, fin thickness and heat resistance as established for a heat sink of Example 1 of the invention.

FIG. 3 is a graph showing the relationship between the fin interval, fin thickness and heat resistance as established for a heat sink of Example 2 of the invention.

FIG. 4 is a graph showing the relationship between the fin interval and the fin thickness as established for the heat sinks of Examples of the invention, Comparative Example and Reference Example.

### BEST MODE OF CARRYING OUT THE INVENTION

The mode of carrying out the invention will be described below with reference to the drawings.

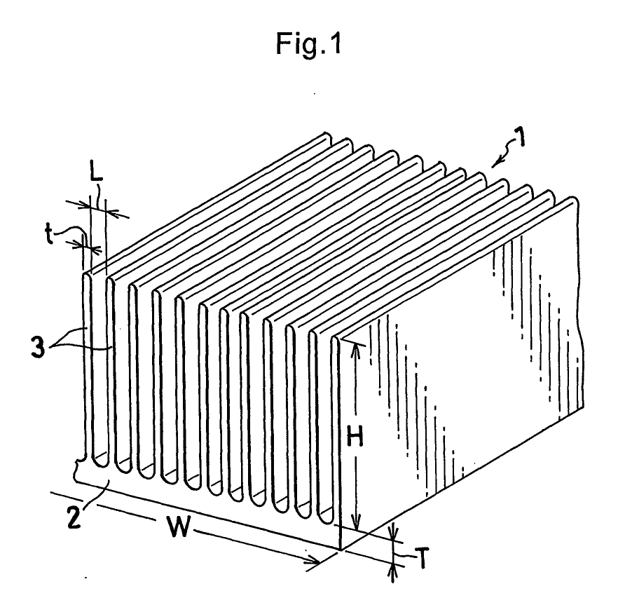

First, FIG. 1 shows a heat sink 1 made of finned aluminum extrudate and according to the invention, for example, for use in electronic devices and information devices having an electronic device incorporated therein. The heat sink 1 comprises a base plate 2, and fins 3 arranged in parallel and provided on one surface thereof. The other surface of the base plate 2 is used for attaching thereto electronic components (heat generating elements) such as thyristors and transistors. It is desirable to use an Al—Mg—Si alloy, such as A6061 or A6063, as the material for the heat sink 1 of aluminum extrudate in view of extrudability and mechanical strength.

Examples of the present invention will be described below along with Comparative Example and Reference Example

### EXAMPLE 1

A heat sink 1 of the invention so shaped as shown in FIG. 1 was prepared from a finned aluminum extrudate. The base plate 2 was 100 mm in width W, 100 mm in length and 2 mm in thickness T. The heat sink weighed 96.1 g. The fins 3 were 0.4 mm in thickness t, 1.4 mm in interval L, 1.8 mm in pitch, 8 mm in height H, and 5.7 in tongue ratio. The heat sink 1 of Example 1 was 0.48 K/W in heat resistance. Typical fan power of 0.1 W for use in cooling electronic devices and information devices incorporating an electronic device was set as a boundary condition.

### Comparative Example

For comparison, a heat sink was prepared from a finned aluminum extrudate. The sink had a base plate 2, which was 100 mm in width and 2 mm in thickness. The heat sink 1 weighed 132.5 g. The fins 3 were 0.9 mm in thickness, 1.4 mm in interval, 2.3 mm in pitch, 8 mm in height, and 5.7 in tongue ratio. The heat sink 1 of Comparative Example was 0.55 K/W in heat resistance.

The experiments for comparison revealed that the heat sink of Example 1 of the invention was 30% greater in fin area than the heat sink of Comparative Example. Further the heat sink 1 exhibited a reduction of 20 to 30% in air flow resistance when the air flow rate at the front side was 1 to 5 m/s to attain an improvement of up to a maximum of about 20% in radiation performance. The heat sink was about 30% smaller in weight.

### EXAMPLE 2

Next, a heat sink 1 was prepared from a finned aluminum extrudate according to the invention. The base plate 2 was 100 mm in width W, 100 mm in length and 2 mm in thickness T. The heat sink weighed 188 g. The fins 3 were 0.4 mm in thickness t, 1.6 mm in interval L, 2.0 mm in pitch, 24 mm in height H, and 15 in tongue ratio. The heat sink 1 of Example 2 was 0.27 K/W in heat resistance. Typical fan power of 0.1 W for use in cooling electronic devices and information devices incorporating an electronic device was set as a boundary condition.

### Reference Example

For comparison, a heat sink was prepared from a finned aluminum extrudate. The sink had a base plate 2, which was 100 mm in width and 2 mm in thickness. The heat sink 1 weighed 326 g. The fins 3 were 1.2 mm in thickness, 1.6 mm in interval, 2.8 mm in pitch, 24 mm in height, and 15 in tongue ratio. The heat sink 1 of Reference Example was 0.29 K/W in heat resistance.

The experiments for comparison revealed that the heat sink of Example 2 of the invention was 40% greater in fin area than the heat sink of Reference Example. Further the heat sink 1 exhibited a reduction of 20 to 30% in air flow resistance when the air flow rate at the front side was 1 to 5 m/s to attain an improvement of up to a maximum of about 20% in radiation performance. The heat sink was about 14% smaller in weight.

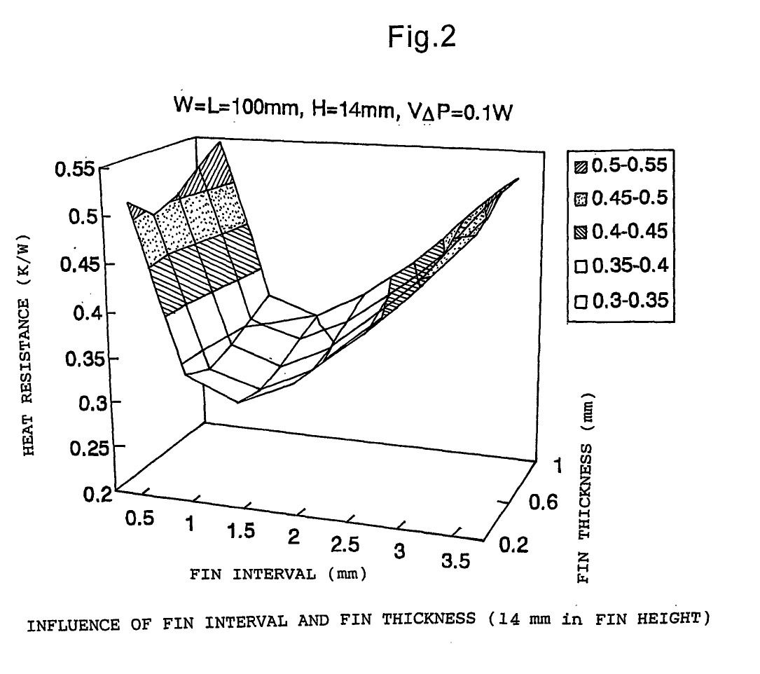

Next, FIG. 2 shows the relationship involved in radiation performance between the interval L of the fins 3, the thickness t thereof and the heat resistance K/W, as established for the heat sink 1 of finned aluminum extrudate according to the invention in the case where the height H of the fins 3 was 14 mm. Typical fan power of 0.1 W for use in cooling electronic devices and information devices incorporating an electronic device was set as a boundary condition.

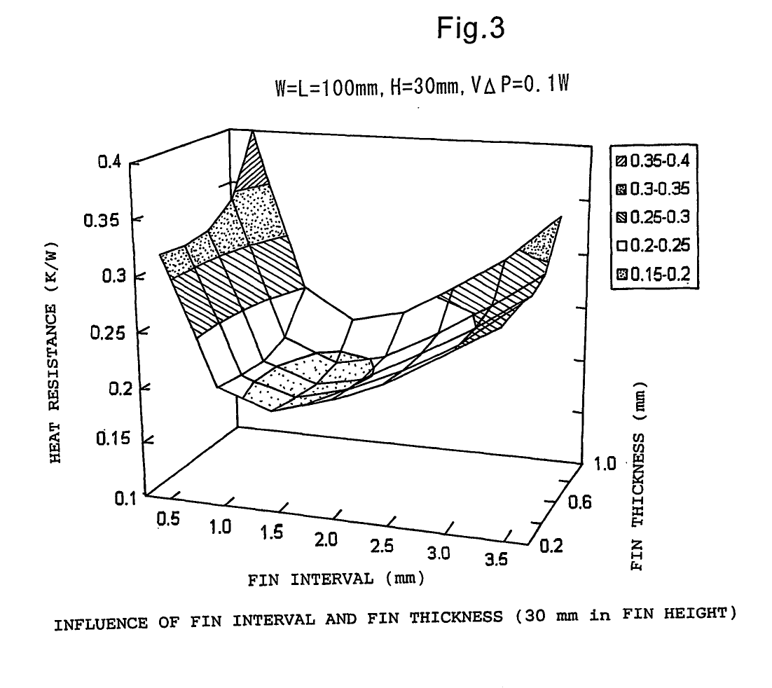

Further FIG. 3 shows the relationship involved in radiation performance between the interval L of the fins 3, the thickness t thereof and the heat resistance K/W, as established for the heat sink 1 of finned aluminum extrudate according to the invention in the case where the height H of the fins 3 was 30 mm. Typical fan power of 0.1 W for use in cooling electronic devices and information devices incorporating an electronic device was set as a boundary condition.

The results of FIGS. 2 and 3 reveal that the fins which are low in heat resistance, that is, high in radiation performance, are 0.1 to 0.8 mm in thickness t and 1 to 1.9 mm in interval L.

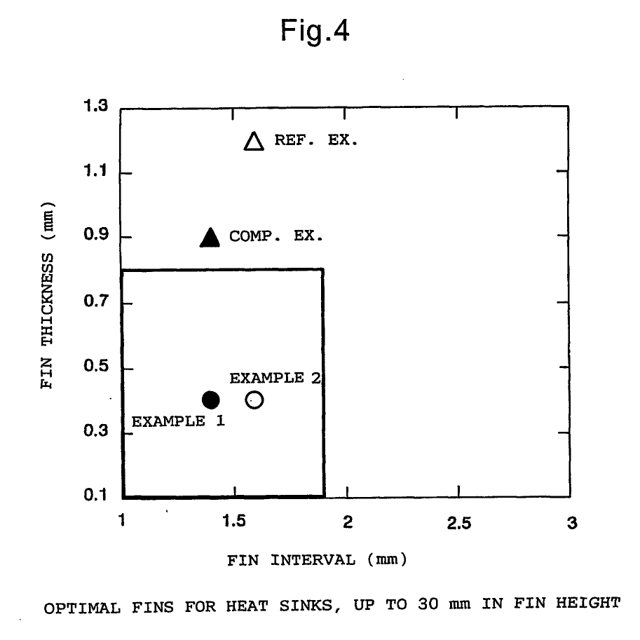

Like experiments conducted with use of heat sinks which were different variously in the height H of fins 3 indicate that when the fins 3 are in the range of 1 to 30 mm in height H, the ranges of optimum values for the interval L of the fins 3 and the thickness t thereof are the same as above. Accordingly, when the fins 3 are up to 30 mm, i.e., in the range of 1 to 30 mm, in height, there exist optimum fin intervals and fin thicknesses as shown in FIG. 4.

With the device of the present invention, the thickness of the fins 3 is reduced within a predetermined range to thereby ensure diminished resistance to the flow of air, improved radiation performance and reduced weight. When used, for example, in electronic devices and information devices incorporating an electronic device, the heat sink 1 exhibits outstanding radiation performance, apparently contributing to a reduction in the size of the cases of the electronic devices and information devices and to the diminution of the weight of these devices.

1. A heat sink comprising a base plate (2), and fins (3) arranged in parallel and provided on one surface thereof, the base plate (2) being 25 to 400 mm in width, 25 to 400 mm in length and 2 to 5 mm in thickness, the fins (3) being 1 to 30 mm in height, 1 to 1.9 mm in interval and 0.1 to 0.8 mm in thickness.

2. A heat sink according to claim 1 wherein the base plate (2) is 50 to 200 mm in width, 25 to 200 mm in length and 2 to 3 mm in thickness, and the fins (3) are 5 to 30 mm in height, 1.5 to 1.9 mm in interval and 0.2 to 0.49 mm in thickness.

3. A heat sink according to claim 1 wherein the base plate (2) is 50 to 200 mm in width, 25 to 200 mm in length and 2 to 3 mm in thickness, and the fins (3) are 5 to 25 mm in height, 1.6 to 1.8 mm in interval and 0.2 to 0.49 mm in thickness.

4. A heat sink according to any one of claims 1 to 3 which has a tongue ratio (H/L=the ratio of the height of the fins/the interval between the fins) of 0.53 to 30.

5. A heat sink according to claim 4 which has a tongue ratio of 2.7 to 24.

6. A heat sink according to any one of claims 1 to 5 which is made of a finned aluminum extrudate.
